(19) United States
(12) Patent Application Publication
(10) Pub. No.: US 2010/0019385 A1
(43) Pub. Date: Jan. 28, 2010

(54) Implementing Reduced Hot-Spot Thermal Effects for SOI Circuits

(75) Inventors: Gerald Keith Bartley, Rochester, MN (US); Todd Alan Christensen, Rochester, MN (US); Paul Eric Dahlen, Rochester, MN (US); John Edward Sheets, II, Zumbrota, MN (US)

Correspondence Address: IBM CORPORATION;ROCHESTER IP LAW DEPT 917, 3605 HIGHWAY 52 N, ROCHESTER, MN, 55901-7829, US

(73) Assignee: INTERNATIONAL BUSINESS MACHINES CORPORATION, Armonk, NY (US)

(21) Appl. No.: 12/178,029

(22) Filed: Jul. 23, 2008

(51) Int. Cl. H01L 21/71; H01L 23/34

(52) U.S. Cl. 257/741; 438/674; 257/E23.08; 257/E21.536

(57) ABSTRACT

Methods and structures are provided for implementing reduced hot spot thermal effects for silicon-on-insulator (SOI) circuits. A silicon-on-insulator (SOI) structure includes a silicon substrate layer, a thin buried oxide (BOX) layer carried by the silicon substrate layer, an active layer carried by the thin BOX layer, and a pad oxide layer carried by the active layer. A thermal conductive path is built to reduce thermal effects of a hotspot area in the active layer and extends from the active layer to the backside of the SOI structure. A trench etched from the topside to the active layer, and is filled with a thermal connection material. A thermal connection from a backside of the SOI structure includes an opening etched into the silicon substrate layer from the backside and filled with a thermal connection material.

### FIELD OF THE INVENTION

The present invention relates generally to the field of manufacturing semiconductor devices, and more particularly, relates to a method and structures for implementing reduced hot spot thermal effects for silicon-on-insulator (SOI) circuits.

### DESCRIPTION OF THE RELATED ART

Silicon-on-insulator (SOI) transistors provide better performance at low operating voltages than do transistors of similar dimensions fabricated in bulk silicon substrates. Superior performance of SOI transistors at low operating voltage is related to the relatively lower junction capacitances obtained on an SOI device as compared to a bulk silicon device of similar dimensions. A buried oxide (BOX) layer in an SOI device separates active transistor regions from the bulk silicon substrate, reducing junction capacitance.

Typical semiconductor applications today have reached the point where the ability to keep the device junction temperatures under the limitations established for reliability and/or function and performance requirements are severely limited. These issues are exasperated by the fact that the power dissipation for chips such as processors, controllers, and the like, are not uniformly dissipated across the surface of the silicon.

Areas where performance matters most are also usually the same areas with the highest power density. Higher power density leads to higher temperatures. For example, there can be a 10-15 degree-C., or perhaps higher, temperature difference between the average and the peak temperature across a chip.

The higher temperature regions are often referred to as hot spots. The hot-spot temperatures lead to higher local leakage currents, which can further aggravate the situation. To control reliability issues, leakage, and to maintain the timing and performance expectations for a specific series of logic gates, the junction temperature is usually specified in a form such as an average temperature, and a peak temperature or not to exceed temperature.

This difference in temperature causes the same circuit in a cooler operating area to have a different performance and reliability than that of a hot-spot area.

U.S. Pat. No. 5,773,362 issued Jun. 30, 1998 to Tonti et al., and assigned to the present assignee, discloses a simple and low cost ultra large scale integrated (ULSI) circuit package and integrated heatsink that efficiently removes heat from a silicon package by integrating the heat sink material into the silicon die, transforming the present two-dimensional art into three dimensions. The fabrication of a high power integrated ULSI package and heatsink begins by fabricating an integrated circuit wafer up to the point of dicing the wafer into individual chips. The front side of the wafer is protected, while the backside of the wafer is exposed. The exposed backside is roughened by chemical and/or mechanical process. Optionally, a gettering process is then performed to remove impurities. The roughened backside is then coated with metal interlayers, preferably aluminum (Al) by chromium (Cr). A layer of copper (Cu) is optionally coated on the metal interlayers. A highly conductive reflowable material, such as solder or gold eutectic, is deposited on the metal interlayers. At this point, the wafer is diced to form chips. The heatsink itself is prepared by first optionally roughening the surface and metalizing the backside of the heatsink with metal interlayer. Next, the chip is thermally attached to the heatsink by reflowing the thermally conductive reflowable material.

U.S. Pat. No. 7,170,164 issued Jan. 30, 2007 to Chen et al., and assigned to the present assignee, discloses a cooling system for a semiconductor substrate that includes a plurality of trenches formed from a backside of the semiconductor substrate, and thermally conductive material deposited in the plurality of trenches. A method of forming cooling elements in a semiconductor substrate, includes coating a backside of the semiconductor substrate with a first mask layer, forming a plurality of trench patterns in the first mask layer, etching the semiconductor substrate to form a plurality of trenches along the plurality of trench patterns, and depositing thermally conductive material in the plurality of trenches. Trenches constructed from the backside of a wafer improve efficiency of heat transfer from a front-side to the backside of an integrated-circuit chip. The fabrication of trenches from the backside of the wafer allows for increases in the depth and number of trenches, and provides a means to attach passive and active cooling devices directly to the backside of a wafer.

A need exists for an effective mechanism for reducing the delta-temperature between the hottest and coolest areas for silicon-on-insulator (SOI) circuits to allow an integrated-circuit chip to run faster, and at better reliability.

### SUMMARY OF THE INVENTION

Principal aspects of the present invention are to provide methods and structures for implementing reduced hot spot thermal effects for silicon-on-insulator (SOI) circuits. Other important aspects of the present invention are to provide such methods and structures for implementing reduced hotspot thermal effects for silicon-on-insulator (SOI) circuits substantially without negative effect and that overcome many of the disadvantages of prior art arrangements.

In brief, methods and structures are provided for implementing reduced hot spot thermal effects for silicon-on-insulator (SOI) circuits. A silicon-on-insulator (SOI) structure includes a silicon substrate layer, a thin buried oxide (BOX) layer carried by the silicon substrate layer, an active layer carried by the thin BOX layer, and a pad oxide layer carried by the active layer. A thermal conductive path is built to reduce thermal effects of a hotspot area in the active layer. The thermal conductive path extends from the active layer to the backside of the SOI structure. Topside processing includes a trench etched through the pad oxide layer, the active layer, and the BOX layer into the silicon substrate layer. The etched trench is filled with a thermal connection material. A thermal connection from a backside of the SOI structure is formed. An opening is etched into the silicon substrate layer from the backside and filled with a thermal connection material proximate to the hotspot area in the active layer.

In accordance with features of the invention, the BOX layer provides an etch stop for the backside etched opening. Alternatively, the backside etched opening stops within the active layer. In another alternative, the backside etched opening stops at a boundary of the pad oxide layer. In another alternative, a nitride etch stop is deposited between the active layer and the pad oxide layer providing an etch stop for the backside etched opening.

In accordance with features of the invention, the thermal connection and electrically conductive material is tungsten. Alternatively the thermal connection and electrically conductive material includes a selected one of aluminum, copper, titanium and nickel.

In accordance with features of the invention, the thermal connection from the backside of the SOI structure is provided with each power supply rail including ground potential and each positive voltage rail for the SOI circuit.

### BRIEF DESCRIPTION OF THE DRAWINGS

The present invention together with the above and other objects and advantages may best be understood from the following detailed description of the preferred embodiments of the invention illustrated in the drawings, wherein:

FIGS. 1A, 1B, 1C, 1D, and 1E are respective schematic side plan views not to scale illustrating exemplary process steps for fabricating hotspot reduction structures in accordance with a preferred embodiment of the invention;

FIGS. 2A, 2B, and 2C are respective schematic side plan views not to scale illustrating exemplary process steps for fabricating hotspot reduction structures in accordance with another preferred embodiment of the invention;

FIGS. 3A, 3B, and 3C are respective schematic side plan views not to scale illustrating exemplary process steps for fabricating hotspot reduction structures in accordance with another preferred embodiment of the invention;

FIGS. 4A, 4B, and 4C are respective schematic side plan views not to scale illustrating exemplary process steps for fabricating hotspot reduction structures in accordance with another preferred embodiment of the invention; and

FIGS. 5A, 5B, 5C, and 5D are respective schematic side plan views not to scale illustrating exemplary process steps for fabricating hotspot reduction structures in accordance with another preferred embodiment of the invention.

### DETAILED DESCRIPTION OF THE PREFERRED EMBODIMENTS

In accordance with features of one embodiment of the invention, methods and structures are provided for implementing reduced hot spot thermal effects for silicon-on-insulator (SOI) circuits. A thermal conductive path is built to reduce thermal effects of a hotspot area for SOI circuits. The thermal conductive path of the invention extends from the active layer to the backside of the SOI structure.

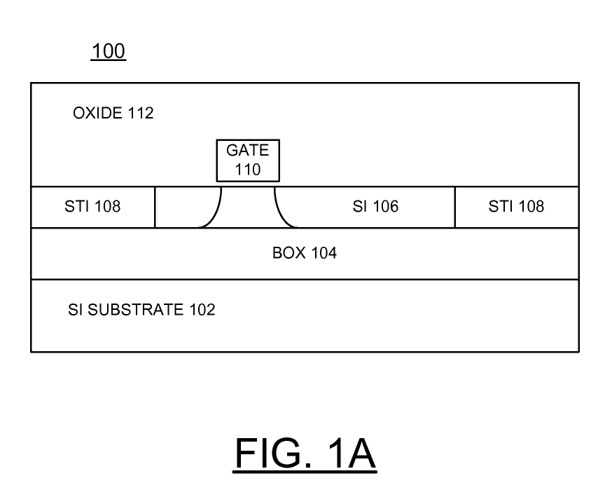

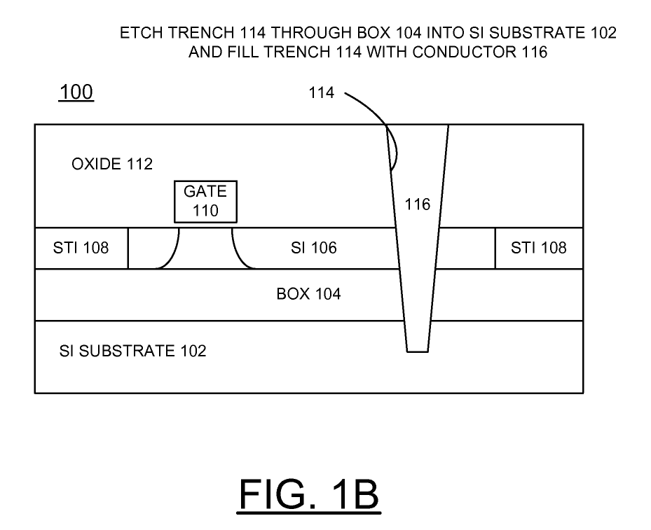

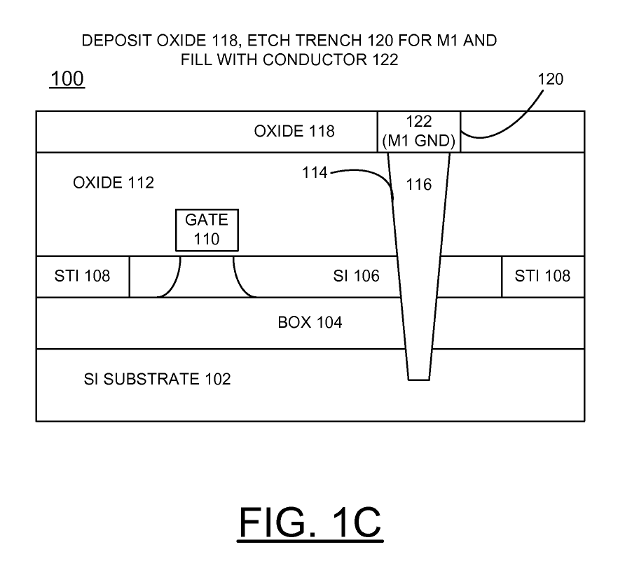

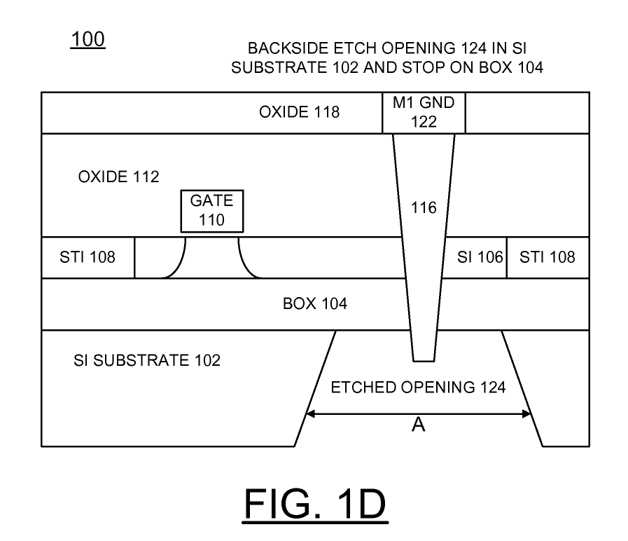

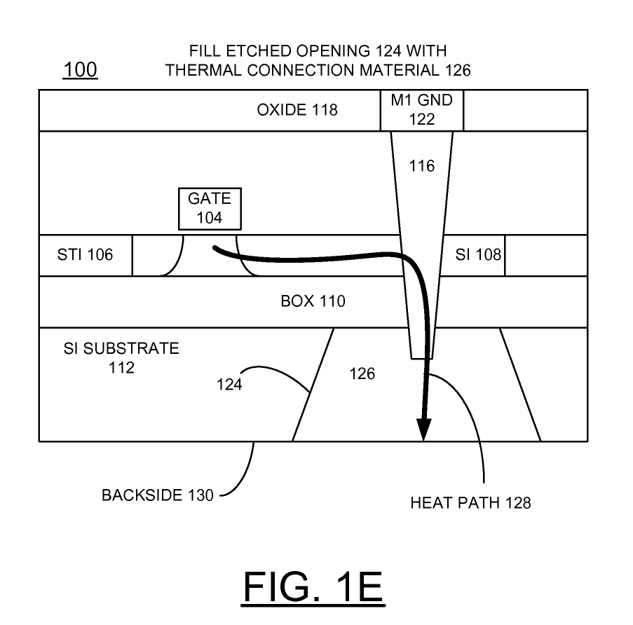

Having reference now to the drawings, FIGS. 1A, 1B, 1C, 1D, and 1E illustrate exemplary process steps for fabricating hotspot reduction structures in accordance with a preferred embodiment of the invention.

In FIG. 1A, there is shown an example silicon-on-insulator (SOI) structure 100 for implementing hotspot reduction structures in accordance with a first preferred embodiment of the invention. SOI structure 100 includes a silicon substrate layer 102, a thin buried oxide (BOX) layer 104 carried by the silicon substrate layer 102, an active layer 106 carried by the thin BOX layer 104, a shallow trench isolation (STI) region 108 is formed in the active layer 106 supporting a device gate electrode 110 and a pad oxide layer 112 carried by the active layer 106. Conventional SOI processing is performed to provide the illustrated SOI structure 100 of FIG. 1A.

In FIG. 1B, topside processing of the SOI structure 100 includes etching a trench 114 through the pad oxide layer 112, the active layer 106, and the BOX layer 104 into the silicon substrate layer 102. The etched trench 114 is filled with a conductor or thermal connection material 116.

In FIG. 1C, an oxide 118 is deposited on the SOI structure 100 and a trench 120 is etched for a wire level (M1) metallization layer or conductor 122. Conventional SOI processing is performed to provide the illustrated SOI structure 100 of each of FIGS. 1A, 1B, and 1C.

In FIG. 1D, a backside processing step is shown in the SOI structure 100 to form a thermal connection from a backside of the SOI structure. Backside processing of the SOI structure 100 includes etching an opening 124 into the silicon substrate layer 102 and stopping on the BOX layer 104. The etched opening 124 has a selected width indicated by an arrow A to provide a thermal hotspot reduction connection to multiple devices formed in the active layer 106.

In FIG. 1E, a backside processing step is shown in the SOI structure 100 with the backside etched 124 filled with a thermal connection and electrically conductive material 126. A heat conduction path 128 indicated by an arrow is formed within or proximate to the hotspot area from the active layer to a backside 130 of the completed wafer or SOI structure 100.

A preferred material for the conductor or thermal connection material 116 and the thermal connection and electrically conductive material 126 is tungsten; while other materials, such as aluminum, copper, titanium and nickel can be used.

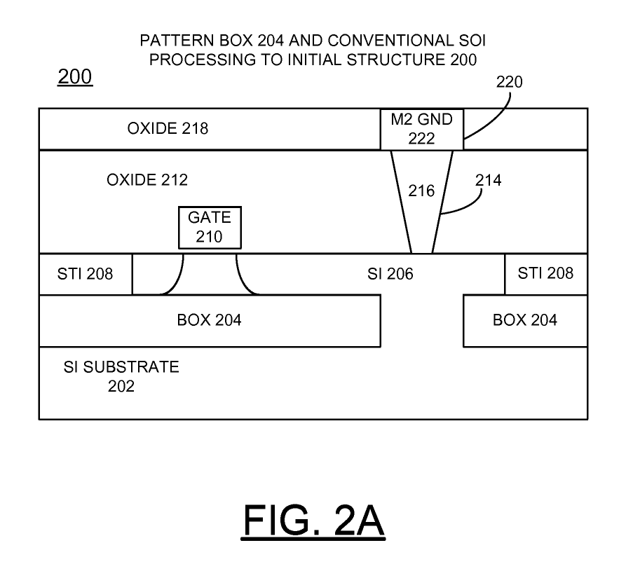

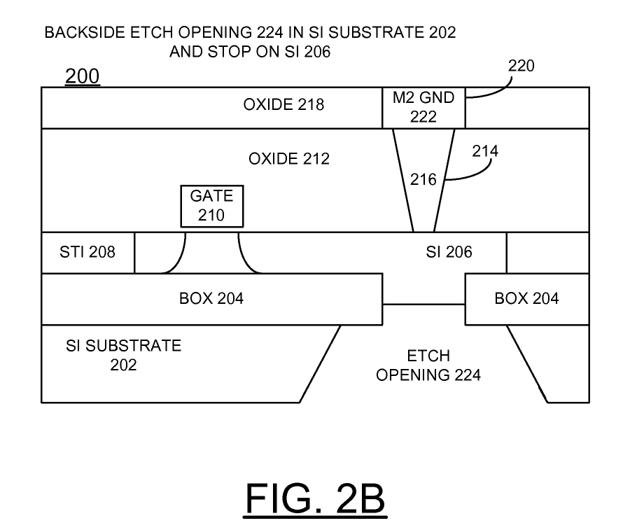

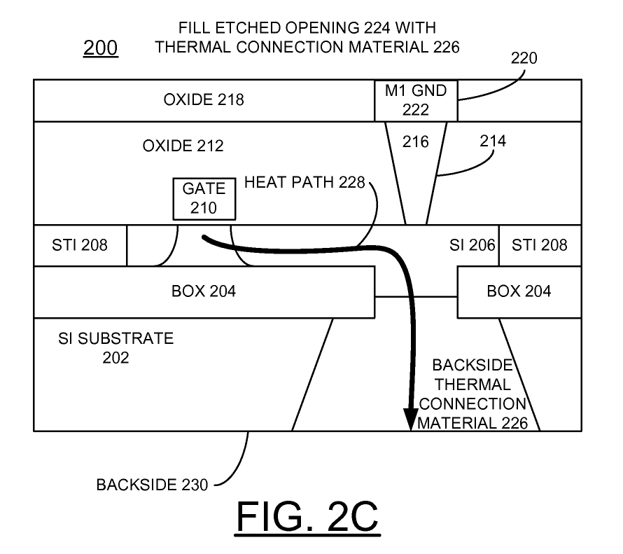

Referring now to FIGS. 2A, 2B, and 2C, there are shown exemplary process steps for fabricating hotspot reduction structures in accordance with another preferred embodiment of the invention.

In FIG. 2A, an example silicon-on-insulator (SOI) structure 200 for implementing hotspot reduction structures in accordance with another preferred embodiment of the invention. SOI structure 200 includes a silicon substrate layer 202, a thin buried oxide (BOX) layer 204 carried by the silicon substrate layer 202, an active layer or silicon layer 206 carried by the thin BOX layer 204, a shallow trench isolation (STI) region 208 is formed in the active layer 206 supporting a device gate electrode 210 and a pad oxide layer 212 carried by the active layer 206. Topside processing of the SOI structure 200 includes etching a trench 214 through the pad oxide layer 212 to the active layer 206 and filling the etched trench 214 with a conductor or thermal connection material 216. An oxide 218 is deposited on oxide 212 of the SOI structure 200 and a trench 220 is etched for a wire level (M1) metallization layer or conductor 222. Conventional SOI processing is performed to pattern the BOX layer 204 and provide the illustrated SOI structure 200 of FIG. 2A.

In FIG. 2B, a backside processing step is shown in the SOI structure 200 to form a thermal connection from a backside of the SOI structure. Backside processing of the SOI structure 200 includes etching an opening 224 into the silicon substrate layer 202 and stopping within the active layer 206.

In FIG. 2C, a second backside processing step is shown in the SOI structure 200 with the backside etched opening 224 being filled with a thermal connection and electrically conductive material 226. A heat conduction path 228 indicated by an arrow is formed within or proximate to the hotspot area from the active layer to a backside 230 of the completed wafer or SOI structure 200.

The preferred material for the conductor or thermal connection material 216 and the thermal connection and electrically conductive material 226 is tungsten; while other materials, such as aluminum, copper, titanium and nickel can be used.

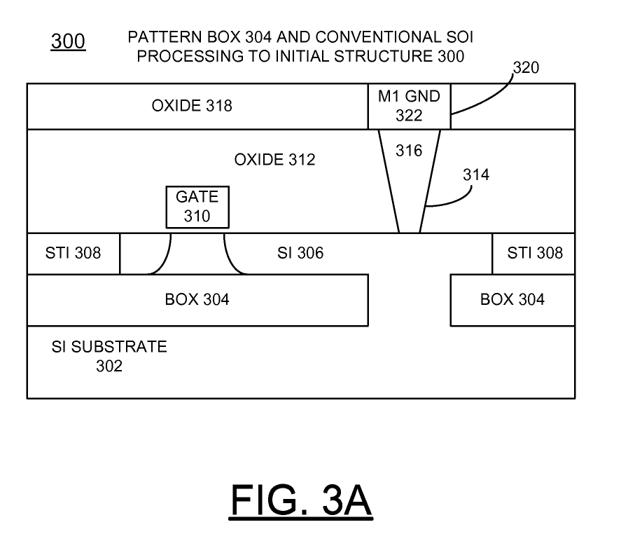

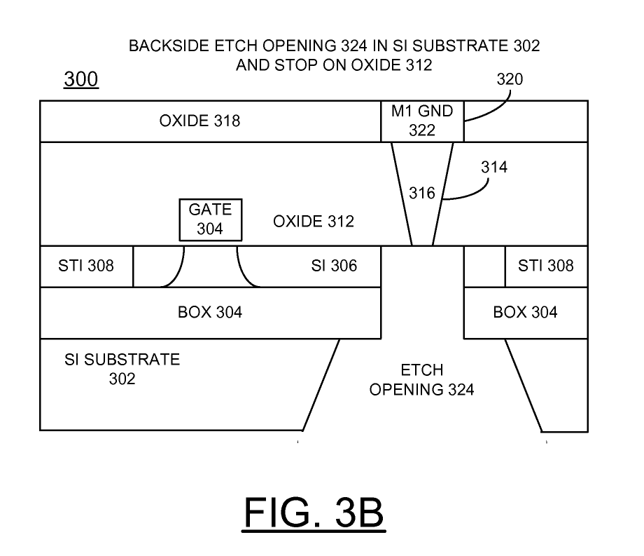

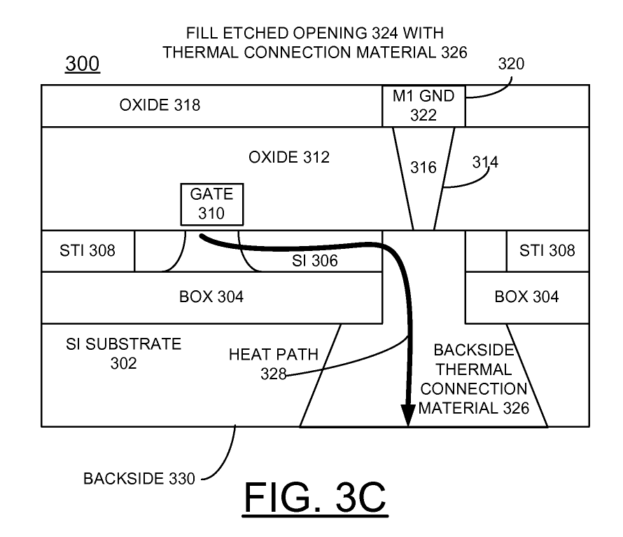

Referring now to FIGS. 3A, 3B, and 3C, there are shown exemplary process steps for fabricating hotspot reduction structures in accordance with another preferred embodiment of the invention.

In FIG. 3A, an example silicon-on-insulator (SOI) structure 300 for implementing hotspot reduction structures in accordance with another preferred embodiment of the invention. SOI structure 300 includes a silicon substrate layer 302, a thin buried oxide (BOX) layer 304 carried by the silicon substrate layer 302, an active layer or silicon layer 306 carried by the thin BOX layer 304, a shallow trench isolation (STI) region 308 is formed in the active layer 306 supporting a device gate electrode 310 and a pad oxide layer 312 carried by the active layer 306. Topside processing of the SOI structure 300 includes etching a trench 314 through the pad oxide layer 312 to the active layer 306 and filling the etched trench 314 with a conductor or thermal connection material 316. An oxide 318 is deposited on the pad oxide 312 of the SOI structure 300 and a trench 320 is etched for a wire level (M1) metallization layer or conductor 322. Conventional SOI processing is performed to pattern the BOX layer 304 and provide the illustrated SOI structure 300 of FIG. 3A.

In FIG. 3B, a backside processing step is shown in the SOI structure 300 to form a thermal connection from a backside of the SOI structure. Backside processing of the SOI structure 300 includes etching an opening 324 into the silicon substrate layer 302 through the BOX layer 304 and the active layer 306 and stopping on a boundary of the pad oxide layer 312.

In FIG. 3C, a backside processing step is shown in the SOI structure 300 with the backside etched 324 filled with a thermal connection and electrically conductive material 326. A heat conduction path 328 indicated by an arrow is formed within or proximate to the hotspot area from the active layer to a backside 330 of the completed wafer or SOI structure 300.

A preferred material for the conductor or thermal connection material 316 and the thermal connection and electrically conductive material 326 is tungsten, while other materials, such as aluminum, copper, titanium and nickel can be used.

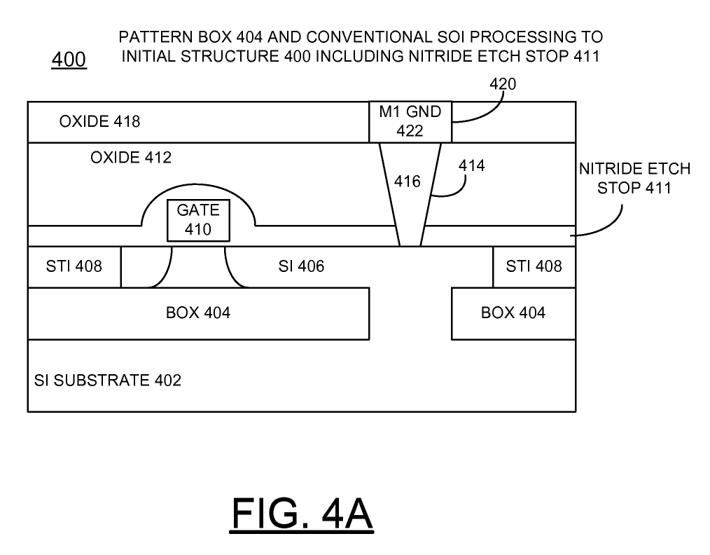

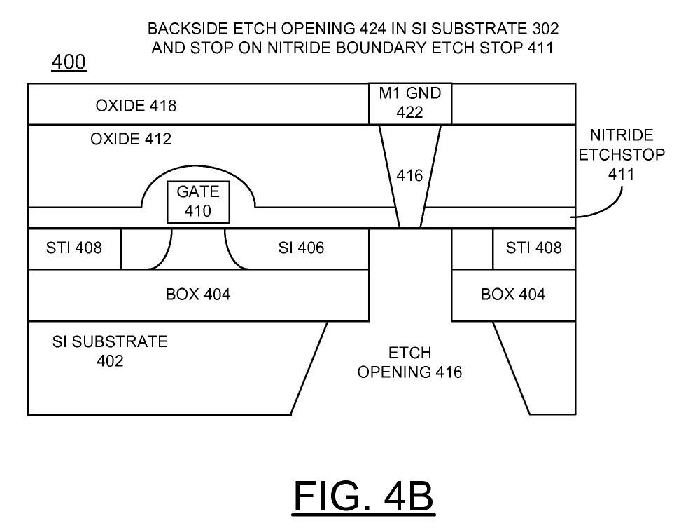

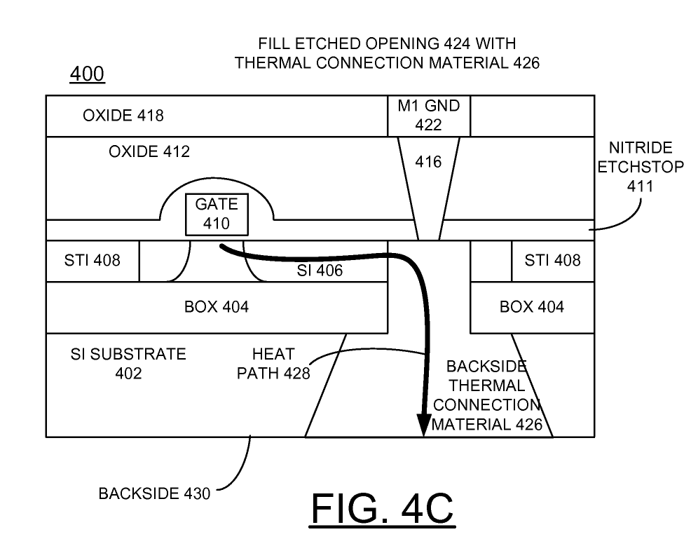

Referring now to FIGS. 4A, 4B, and 4C, there are shown exemplary process steps for fabricating hotspot reduction structures in accordance with another preferred embodiment of the invention;

In FIG. 4A, an example silicon-on-insulator (SOI) structure 400 for implementing hotspot reduction structures in accordance with another preferred embodiment of the invention. SOI structure 400 includes a silicon substrate layer 402, a thin buried oxide (BOX) layer 404 carried by the silicon substrate layer 402, an active layer or silicon layer 406 carried by the thin BOX layer 404, a shallow trench isolation (STI) region 408 is formed in the active layer 406 supporting a device gate electrode 410, a nitride etch stop 411 and a pad oxide layer 412 carried by the active layer 406. The nitride etch stop 411 is deposited on the active layer 406, gate electrode 410, and STI 408. Topside processing of the SOI structure 400 includes etching a trench 414 through the pad oxide layer 412 and through the active layer 406 and filling the etched trench 414 with a conductor or thermal connection material 416. An oxide 418 is deposited on the pad oxide 412 of the SOI structure 400 and a trench 420 is etched for a wire level (M1) metallization layer or conductor 422. Conventional SOI processing is performed to pattern the BOX layer 404 and provide the illustrated SOI structure 400 of FIG. 4A with the nitride etch stop 411.

In FIG. 4B, a backside processing step is shown in the SOI structure 400 to form a thermal connection from a backside of the SOI structure. Backside processing of the SOI structure 400 includes etching an opening 424 into the silicon substrate layer 402 through the BOX layer 304 and the active layer 306 and stopping on a boundary of the nitride etch stop 411.

In FIG. 4C, a backside processing step is shown in the SOI structure 400 with the backside etched 424 filled with a thermal connection and electrically conductive material 426. A heat conduction path 428 indicated by an arrow is formed within or proximate to the hotspot area from the active layer to a backside 430 of the completed wafer or SOI structure 400.

A preferred material for the conductor or thermal connection material 416 and the thermal connection and electrically conductive material 426 is tungsten while other materials, such as aluminum, copper, titanium and nickel can be used.

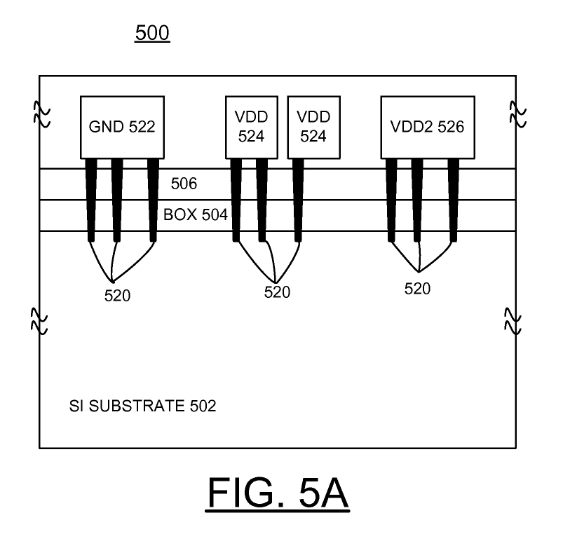

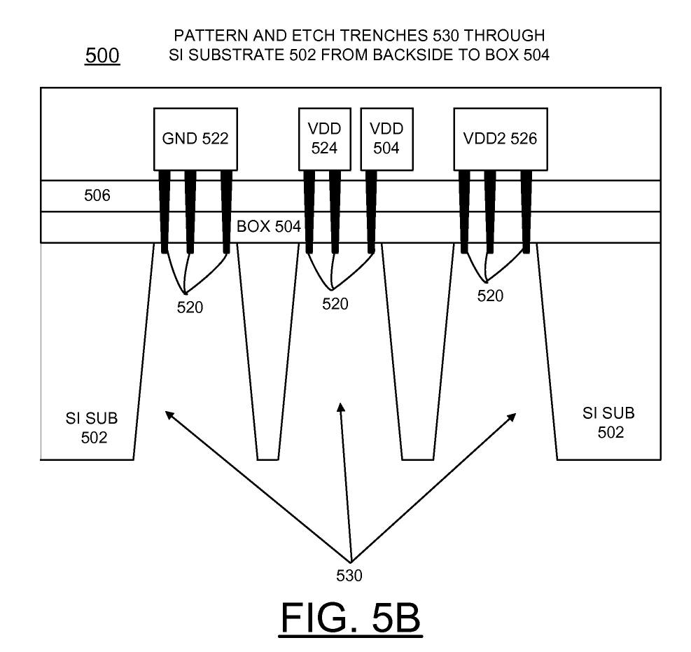

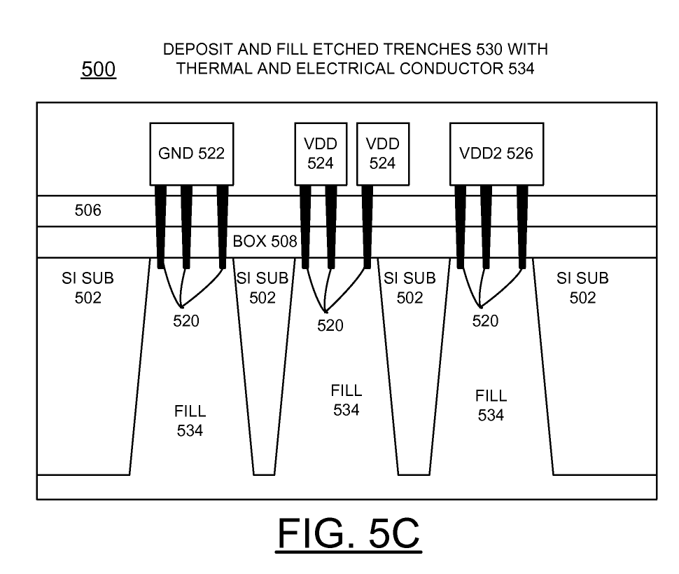

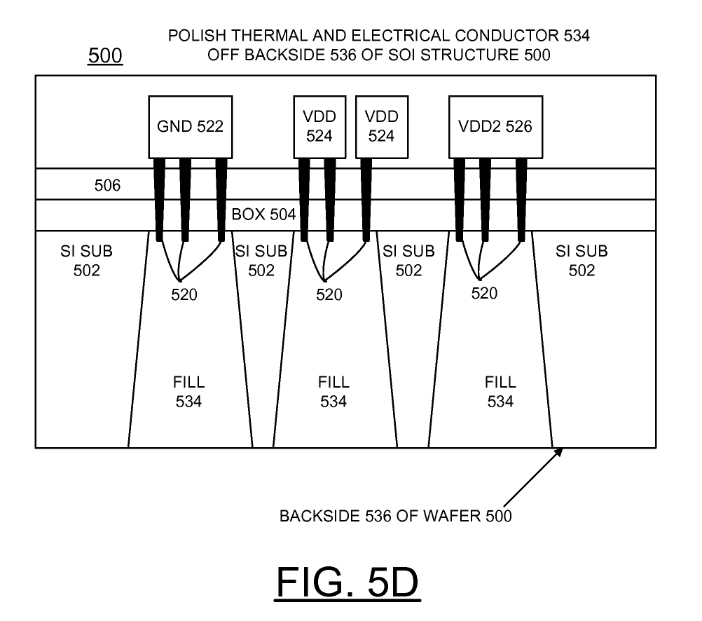

Referring now to FIGS. 5A, 5B, 5C, and 5D, there are shown exemplary process steps for fabricating hotspot reduction structures in accordance with another preferred embodiment of the invention.

In FIG. 5A, an example silicon-on-insulator (SOI) structure 500 for implementing hotspot reduction structures in accordance with another preferred embodiment of the invention. SOI structure 500 includes a silicon substrate layer 502, a thin buried oxide (BOX) layer 504 carried by the silicon substrate layer 502, an active layer or silicon layer 506 carried by the thin BOX layer 504, and a pad oxide 512 carried by the active layer 506. Topside processing of the SOI structure 500 includes forming an etched and filled trench 520 through the pad oxide layer 512, the active layer 506, the BOX layer 504 to the silicon substrate layer 502. The etched and filled trench 520 is filled with a thermal connection material that is thermally and electrically conductive. A respective wire level layer or conductor is provided for power supply rails including ground 522, a first voltage rail VDD 524, and a second voltage rail VDD 526. Conventional SOI processing is performed to provide the illustrated SOI structure 500 of FIG. 5A.

In FIG. 5B, a backside processing step is shown in the SOI structure 500 to form a thermal connection from a backside of the SOI structure. Backside processing of the SOI structure 500 includes pattern and etching a plurality of trenches 530 into the silicon substrate layer 502 and stopping on a boundary of the BOX layer 504.

In FIG. 5C, a backside processing step is shown in the SOI structure 500 with the backside etched trenches 530 filled with a thermal connection and electrically conductive material 534. The thermal connection and electrically conductive material 534 is deposited directly onto the trenches 530.

The preferred material for the thermal connection and electrically conductive material 534 is tungsten; while other materials, such as aluminum, copper, titanium and nickel can be used.

In FIG. 5D, a final backside processing step is shown in the SOI structure 500 with polishing the thermal connection and electrically conductive material 534 off a backside 536 of the wafer forming SOI structure 500.

While the present invention has been described with reference to the details of the embodiments of the invention shown in the drawing, these details are not intended to limit the scope of the invention as claimed in the appended claims.

1. A structure for implementing reduced hot spot thermal effects for silicon-on-insulator (SOI) circuits comprising:
a silicon-on-insulator (SOI) structure,
said SOI structure including a silicon substrate layer, a thin buried oxide (BOX) layer carried by the silicon substrate layer, an active layer carried by the thin BOX layer, and a pad oxide layer carried by the active layer;
a thermal conductive path proximate to a hotspot area in the active layer to reduce thermal effects;
said thermal conductive path extending from the active layer to the backside of the SOI structure;
said thermal conductive path including an etched trench extending from a topside of the SOI structure to the active layer, said etched trench being filled with a thermal connection material; and a thermal connection from a backside of the SOI structure;
said backside thermal connection including a backside etched opening extending from the backside of the SOI structure into the silicon substrate layer and said backside etched opening being filled with a thermal connection material.

2. The structure for implementing reduced hot spot thermal effects as recited in claim 1 wherein said BOX layer provides an etch stop for the backside etched opening.

3. The structure for implementing reduced hot spot thermal effects as recited in claim 1 wherein said backside etched opening stops within the active layer.

4. The structure for implementing reduced hot spot thermal effects as recited in claim 1 wherein said backside etched opening stops at a boundary of the pad oxide layer.

5. The structure for implementing reduced hot spot thermal effects as recited in claim 1 wherein said SOI structure includes a nitride etch stop deposited between the active layer and the pad oxide layer, said nitride etch stop provides an etch stop for said backside etched opening.

6. The structure for implementing reduced hot spot thermal effects as recited in claim 1 wherein said backside etched opening has a selected width for providing said backside thermal connection to multiple devices in a SOI circuit.

7. The structure for implementing reduced hot spot thermal effects as recited in claim 1 wherein said thermal connection material is formed of a thermal and electrically conductive material.

8. The structure for implementing reduced hot spot thermal effects as recited in claim 7 wherein said thermal and electrically conductive material is tungsten.

9. The structure for implementing reduced hot spot thermal effects as recited in claim 1 wherein said thermal and electrically conductive material is a selected one of aluminum, copper, titanium and nickel.

10. The structure for implementing reduced hot spot thermal effects as recited in claim 1 wherein said thermal connection from the backside of the SOI structure is provided with power supply rails.

11. The structure for implementing reduced hot spot thermal effects as recited in claim 10 wherein said power supply rails include ground potential and at least one positive voltage rail for the SOI circuit.

12. A method for implementing reduced hot spot thermal effects for silicon-on-insulator (SOI) circuits in a silicon-on-insulator (SOI) structure, said SOI structure including a silicon substrate layer, a thin buried oxide (BOX) layer carried by the silicon substrate layer, an active layer carried by the thin BOX layer, and a pad oxide layer carried by the active layer; said method comprising:
providing a thermal conductive path proximate to a hotspot area in the active layer to reduce thermal effects;
forming said thermal conductive path extending from the active layer to the backside of the SOI structure including
etching a trench extending from a topside of the SOI structure to the active layer, and filling said etched trench with a thermal connection material; and
forming a thermal connection from a backside of the SOI structure including etching a backside etched opening extending from the backside of the SOI structure into the silicon substrate layer, and filling said backside etched opening with a thermal connection material.

13. The method for implementing reduced hot spot thermal effects as recited in claim 12 wherein both filling said etched trench with a thermal connection material and filling said backside etched opening with a thermal connection material includes providing said thermal connection material formed of a thermal and electrically conductive material.

14. The method for implementing reduced hot spot thermal effects as recited in claim 13 wherein said thermal and electrically conductive material is tungsten.

15. The method for implementing reduced hot spot thermal effects as recited in claim 13 wherein said thermal and electrically conductive material is a selected one of aluminum, copper, titanium and nickel.

16. The method for implementing reduced hot spot thermal effects as recited in claim 12 wherein etching said backside etched opening includes providing an etch stop of said BOX layer for the backside etched opening.

17. The method for implementing reduced hot spot thermal effects as recited in claim 12 wherein etching said backside etched opening includes providing an etch stop within the active layer.

18. The method for implementing reduced hot spot thermal effects as recited in claim 12 wherein etching said backside etched opening includes providing an etch stop at a boundary of the pad oxide layer.

19. The method for implementing reduced hot spot thermal effects as recited in claim 12 wherein etching said backside etched opening includes providing a nitride etch stop deposited between the active layer and the pad oxide layer of said SOI structure, said nitride etch stop provides an etch stop for said backside etched opening.

20. The method for implementing reduced hot spot thermal effects as recited in claim 12 includes providing said thermal connection from the backside of the SOI structure with power supply rails, said power supply rails including ground potential and a positive voltage rail for the SOI circuit.
